(19) United States
(12) Patent Application Publication
(10) Pub. No.: US 2005/0013102 A1
(43) Pub. Date: Jan. 20, 2005

(54) Holder for at least one portable computer and use of such a holder

(76) Inventor: Stig Poulsen, Sjaelland (DE)

Correspondence Address: Stig Poulsen, Agerflojen 35, Viby Sjaelland, DK-4130, DK

(21) Appl. No.: 10/493,656

(22) PCT Filed: Oct. 23, 2002
(86) PCT No.: PCT/DK02/00706

(30) Foreign Application Priority Data
Oct. 25, 2001 (DK) PA 2001 01571

(51) Int. Cl. H05K 5/00

(52) U.S. Cl. 361/683

(57) ABSTRACT

The present invention refers to a holder (40) with a working surface (25), specifically for at least one portable computer (3). The holder comprises an up-facing working surface (25) intended to be situated in functioning relationship to the portable (notebook/laptop) computer (3) concerned, so the user (EP) visually can utilize the displaying area (8) of the computer's ready-folded screen (4) simultaneously with her/his working with material placed on the holder's (40) up-facing working surface (25). The working surface (25) of the holder comprises a first delimiting edge (A), intended to be positioned adjacent the ready-folded screen (4), and an opposed edge (B) positioned towards the user. The holder comprises adjust means (29, 31, 32) for relative level-positioning of the notebook-computer (3) concerned to the working surface (25), so said working surface above said computer's lower part (5) comprising keypad (6) etc, is placed between the ready-folded screen (4) and the user (EP), who can watch the whole displaying area (8) unrestricted of the first edge (A) of the working surface (25). The present invention also refers to analogous utilization with a screenunit.

### FIELD OF APPLICATION

The present invention concerns a holder for at least one portable computer, said holder having a substantially planar working surface defined by the up-facing surface above an underlying structure having one or more delimiting edges, the holder being placeable in a functioning relationship to the at least one portable computer having a lower part and a relatively hereto up-pivoted screen part having a displaying area, by the working surface being useable by a user in connection with that user's visual employment of the screen's displaying area from his/her eyepoint of view being substantially positioned in front of the displaying area.

The present invention also relates to an analogous use of the holder according to the present invention with at least one unit containing a screen.

### BACKGOUND DEFINITIONS

By “portable computer” or simply “portable” is meant a fold-up notebook/laptop or the like type computer, wherein the screen with it's display area lidwise is folded adjacent the other main part of the computer (=“the lower part”) by means of a hinge-like means near the back side of the computer structure, the portable being conventionally positioned on a horizontal surface. In the folded state both the downfacing display area and the lower part's upfacing input means—i.e. keypad, pointing devices and the like—are protected e.g. during transport of the collapsed portable.

Conventionally positioned on an up-facing physical placement-plane the portable in an open-folded and ready-to-use state presents the built-in keyboard etc. in front of and at a lower level than the lower edge of the displaying area of the ready-pivoted screen behind—as seen from a conventionally positioned user standing or sitting conventionally.

(The specifications of directions used herein refer to what is normally experienced by a human user conventionally positioned in front of the keypad and screen of such ready-to-use-folded portable computer. At alternative positioning and/or other use the specifications of directions are to be interpreted accordingly.) Portables might possess a functionality at least similar to conventional computers of so-called “desktop”, “PC” or “workstation” type being combined from separate co-working units (CRT-screen, keyboard, cabinet comprising cpu/ram/etc, modem, printer, etc.) and usually being part of a stationary arrangement. Portables might be equipped with numerous and various “ports” for communication with/to units outside the physical limits of the portable proper. Communication to such ports is usually established by means of metallic or light conducting cables, or by means of wireless couplings e.g. based on radiation in or out of more or less directional and/or far reaching electromagnetic and/or pressure waves, the communication always obeying some rule. Examples of such “ports” are socket for power-supply, cable for printer, infrared communication with modem, port for wireless keyboard, connector for mouse or joystick, built-in microphone/speaker/camera and connectors for such external units, connectors for cards comprising a memory or mobile phone, external “drive” or reading unit, and some send/receive function for a radio-/micro-wave based network connection, “blue tooth”-connection or the like.

Portables might also room externally accessible “drives” or compartments with volume and interface for such drives, where drives or medias with or for data storage might be accomodated. Medias for placement in drives or drives for such compartments might have other functionality e.g. as a mobile/satellite telephone, mobile fax or as a fast interface for internet-communication.

By a working surface is meant a—substantially planar—practically continuous area of an appropriate, relevant size, that is at the user's free disposal, whereas the working surface simultaneously is made up from the substantially up-facing upper surface above a relatively stable underlying structure and has a position reasonably adjacent a portable actually utilized by the same user. During her/his use of the portable by regarding the screen's displaying area, the user may on the working surface e.g. place books or printed matter for reading/noting.

### PRIOR ART, THE PROBLEMS HEREWITH AND THE NEED FOR THE INVENTION

A known holder, which might be useable with portable computers is consisted of an ordinary table, where the table top possibly with an overlying blotting pad or the like can perform as the substantially planar upfacing working surface, as the table is positionable in a functioning relationship to at least one portable computer. Such functioning relationship to the portable consists in the computer concerned being positioned up-folded and ready for use (“ready-folded”) on the surface of the table top in such a way, that the areas of the table top proper around and especially in front of and to the sides of the portable, are at the free disposal of a user conventionally positioned at a delimiting edge of the table top, and thus are making up the working surface. The table top's possible area behind the ready-folded screen is not reasonably easily accesssible to the user simultaneously visually utilizing the screen's displaying area, so such an area is not considered constituting an essential part of the working surface. In the situation just described, the placement plane, whereon the portable in principle is resting, is substantially coincident with the working surface.

From U.S. Pat. No. 6,256,193-B1 is known a vertical docking and positioning apparatus for a portable computer to support the portable computer in an inclined position with the screen raised for better viewing and for increased desktop space efficiency, as said patent's invention takes up less space on the desk than if the portable computer was lying flat on the desk. The portable computer is placed onto the front surface of an inclined docking platen or the like, the inclined position of the portable's base possibly also facilitating up-streaming cooling of the portable. The holder itself is to be positioned on e.g. the top of a desk in an office environment, thus leaving to the desktop/surface, where the holder is positioned, for providing a working surface in the same manner as mentioned above. Such docking apparatus might optionally be embodied as art enclosed dock housing whose front surface in addition to providing an aesthetic covering for the keyboard provides a “billboard-like” place for holding e.g. “post-it” (self-adhering type) notes.

From WO-00/48065-A2 is known a keyboard wrist support/palm rest configured as a relocatable platform for the resting of the computer operator's palms/wrists in a comfortable position relative to the keyboard—also for use with a portable computer having an integral keyboard; here, the wrist support additionally might help counterbalancing the weight of the portable's “opened”, visible display e.g. by means of the downward force exerted from the operators wrists to the support platform. If not being more or less integrated in/with the (thus proprietarily designed) computer chassis, the wrist support might be constructed as a separate holder-like unit for a portable computer. In the functioning combination (t)hereof, the support platform in a first position (i.e. in use) always is positioned between the computer's integral keyboard and the user hereof; the support platform might be slidable approx. parallelly above the plane of the keyboard for “horizontal” adjustment in use to a convenient operating position situated between the keyboard and the operator; in a second position (i.e. out of use, where the portable computer's top portion comprising the display is expected to be “closed” to cover the integral keyboard in the bottom chassis portion) the support platform is positioned elsewhere preferably below the computer's chassis.

U.S. Pat. No. 5,697,686-A and U.S. Pat. No. 6,012,788-A illustrate other examples of known holders intended for at least one portable computer, the holder having a substantially planar up-facing working surface and can be positioned in functioning relationship to a portable.

A common feature at known holders of relevant type for portable computers is, that—if these holders at all exhibit a working surface—this, possibly parted, working surface is positioned at one/both side(s) to and/or in front of/behind the lower part and the ready-folded screen of the portable computer utilized, causing many inconveniences to the user. E.g. the arrangement with two separate working surface parts—one to each side to the portable computer, as specified in U.S. Pat. No. 6,012,788-A—yields substantial drawbacks in it being both difficult to the user to administer the use of separate working surface areas, and extremely fatiguing to the user from the eye-point of view to have to endure a working situation with shifting among many, very different directions of observation and working.

From DE-3,240,078-A1 a holder is known comprising a working surface (i.e. the top face of the plate 6 in the figures of this publication). This holder is at the time of its creation (before Oct. 30, 1982) especially designed for use with a computer-terminal's CRT-screen and the accompanying separate keyboard. A holder known from DE-3,240,078-A1 can have a ready-to-use portable laptop/notebook computer with ready-folded screen positioned instead of and on the same location as the CRT-screen-unit (i.e. solely on the plate 2 in the figures of said publication). Such configuration also represents the most relevant known prior art, which is specified in the preamble of claim 1.

Until now each user also had to accept, that if (s)he wants to establish a working surface in front of her-/him-self, the portable has to be positioned farther away, so the working surface can have a situation in front of the lower part of the computer and towards the user. The drawbacks by this are substantial, as the viewing distance to the screen is augmented, and both directions of view, and the focusing distances from the eyepoint to the screen's displaying area and to the working surface, at the same time are becoming substantially different. Further the user's viewing work is rendered tiring from the sight to the working surface being partly blocked from especially the user's arms, as these have to be stretched forwards to activate the up-facing input means on the portable's lower part. Operation of the input means during a prolonged time this way with lifted, almost completely strethed-forward arms also with a high probability causes injuries and/or phenomena of tiredness in the back and shoulders of the user.

Therefore there is a need for provision of a working surface, at a portable computer utilized with ready-folded screen, with a position, which from almost all—users is regarded as the most needed—it being closely in front of the ready-folded screen of the portable computer utilized. This need is further perspectivated by an extremely disadvantageous—but nevertheless often chosen—emergency solution to establish an aimed working zone right in front of the screen during work with a portable related to handling/reading information from paper or like material with a limited heaviness, consisting in tolerating the absence of a working surface and placing the material directly on the lower part, while e.g. reading. The paper then has to be removed, when the keypad and/or the pointing means on the lower part are to be operated. Such a working situation is extremely unsuitable, as it is complicated and “non-defined”, and further presents a clear risk of unwanted and maybe non-discovered, even fatal, input be given to the computer during handling of the material.

### OBJECT OF THE INVENTION AND ITS FULFILMENT

Therefore an object of the invention is to provide for an actual user of a portable computer, a working surface with an optimal situation closely in front of the ready-folded screen and thus above the lower part of the portable computer.

With the invention is created a holder—especially intended for at least one portable computer—comprising a substantially planar and up-facing working surface and with a possibility for placement in functioning relationship to at least this one portable computer, as the above object is fulfilled by the holder according to the present invention providing a working surface between the user and the portable computer's ready-folded screen, having an optimum situation above the portable computer's lower part and close to the screen's displaying area.

### WHAT ESPECIALLY IS OBTAINED BY THE INVENTION

At at least one portable computer, which the invention's holder can be positioned in functioning relationship to, the holder establishes at least a part of its working surface above the lower part of the portable computer concerned—between the displaying area and the user—and with an optimal position, as a desired part of, preferably the whole, displaying area of screen concerned from the user's eyepoint is visible above the (part of the) working surface in front of the screen. By this, the differences in both direction of view, and distance of focusing, to/from the displaying area of the pivoted screen and the working surface of the holder (and the articles thereon) are substantially reduced for the user, compared to what is achieveable by known holders/working surfaces. This eliminates the abovementioned drawbacks hitherto endured by the users, and yields a substantial ergonomic improvement of the user's working situation during the employment of a portable. Moreover the holder according to the invention supersedes the mentioned disadvantageous emergency solution with placing the paper directly on the portable's keypad. The damages in the user's shoulders/back and the tiredness in the user's eyes and back of the neck from the stressing conditions of viewing, resulting from the prior-art positioning of the portable computer with the keypad situated between the working surface and the screen, can also be eliminated by the invention.

Thus, summarized, are with the holder according to the invention achieved a substantially improved ergonomics in the user's working situation with the portable computer plus the percieved benefits related thereto, which also can be of a psychological nature.

### THE PRESENT INVENTION'S SPECIAL TECHNICAL MEANS

As characterizing means the invention's holder firstly has a structure below at least a part of the working surface, shaped so that a first limiting edge here can have a position substantially adjacent in front of the displaying area of the ready-folded screen of at least one portable computer, to which the holder is positioned in functioning relationship, and so a limiting edge compared to the first limiting edge can be positioned nearer a user of the portable computer actually concerned, whereby at least a part of the working surface can be established above the lower part of the portable computer concerned—between the displaying area and the user.

Secondly the holder according tO the invention possesses characterizing means for relative level-placement of the at least one portable computer with ready-folded screen actually concerned to at least a part of the working surface established above said computer's lower part, so that a desired part of, preferably the whole, displaying area of the screen with the effects of these means, as seen from the user's eyepoint of view can be made visible above the first limiting edge located nearer to the displaying area and above said lower part.

### THE EFFECT OF THE NOVEL MEANS

The special shaping af the holder's structure leads to, that at least of a part of the holder's working surface can be located above the lower part of the portable computer actually concerned, as a first limiting edge can be located adjacent the displaying area of the ready-folded screen, and (said part of) the holder's working surface from this edge to another limiting edge can be extended towards the user.

The holder's special means for relative level-placement yields an adjustment of the relative level-difference between the (part of the) working surface concerned and the lower border of the displaying area of the ready-folded screen of the portable computer actually concerned.

The special, combined effect of the special means of the holder according to the invention is therefore, that a desired part of the, preferably the whole, displaying area of the screen concerned, from the user's eyepoint of view can be visible above the first limiting edge of the inventive holder's working surface(-part) being situated between the screen and the user, the first limiting edge being located nearer the displaying area.

For smaller models of portable computers, a design, where the lower part presenting the keypad is just covered from the working surface, will yield an area of the working surface in front of the screen of approx. an A5-landscape size (=210×148.5 mm). Manufactured corresponding to the most common model-size of portable computers, the working surface area in front of the screen will have approx. an A4-landscape size (=297*210 mm).

Working surfaces of these limited dimensions are e.g. well-suited for short term use, where they can serve as support for reading of paperborne printing or writing of notes or the like, which can be related to information, which is given from the portable computer's displaying area e.g. during jotting down train departure-times during consultation of a timetable from a holder according to the invention with a portable computer, placed in a public environment such as a station's vestibule.

Other Embodiments:

(Especially Re. Claim 2:)

In a advantageous embodiment the working surface of the invention's holder one or more places can have its delimiting edge provided as raised barrier.

Especially where or when the holder's working surface is not horizontal, it is practical the edge of the working surface being provided as one or more raised barriers, e.g. as attached strips or up-turned edges of sheet material, so the raised barriers hinder freely lying articles such as separate sheets of paper, ball-pens or the like, to slide or roll over the edge of the working surface.

A non-horizontal working surface can e.g. be present of a holder placed at a level intended for the user be standing, what e.g. might be desired in relation to the just mentioned location of a holder according to the invention for short term, one-time usage in surroundings more or less restrictedly available to public. Especially the strip of the working surface situated between the screen and the user can here advantageously slope towards the user, that a configuration comparable to a classical desk is achieved.

(Especially Re. Claim 3:)

Different models of portable computers can have varying heights of the lower part with the upfacing input means below the plane of the working surface. Also the distance between the lower border of the displaying area and the theoretical hinge-axis for pivoting the screen to collapsed condition are varying among models. For portable computers standing on a horizontal placement plane, their displaying areas pivoted to be vertical (for the sake of comparison) a substantial variation in the distance from the placement plane to the lower border of the displaying areas is demonstrated.

Also, to be able to normally operate the upfacing input means, comprising the keypad, in the lower part of a portable computer positioned in relation to a holder according to the invention, by the fingers, it has shown, that a certain free distance above e.g the keys is required. Even small children's fingers require at least approx. 10 mm clearance above the keys, while the requirement for clearance from a grown-up person's fingers is approx. 35 mm, but very varying with the user's individual key-in technique and relevant physical dimensions and with the size, design and position of the input means at the portable computer concerned. Moreover is has shown much convenient to the user, that the clearance above the lower part is increasing in the direction towards the user.

Therefore, the invention's holder beneficially also can have an embodiment, where the means for relative level-placement are adjustable, so that the theoretical placement plane for the at least one portable computer actually concerned, which the holder is positioned in functioning relationship to, compared to the underside of the structure above the lower part concerned, is adjustable in varying distance and/or in varying slope, which yields a clearance above the lower part preferably augmenting towards the user.

By this, the holder according to the invention also can be placed in functioning relationship to more portable computers simultaneously and/or successively, even if these have different sizes, as the adjustment to the user's needs for clearance above the lower pares input means can be considered.

(Especially Re. Claim 4:)

For the embodiments mentioned until now the surface, whereon the invention's holder is put to be placed in functioning relationship with one or more portable computers, could have been coincident with the placement plane for the portable.

Normally the working surface of a holder according to the invention will be made up of the top side of a plate-structure with adequate surface character, strength and stiffness and of any conceivable suitable material composition or combination. Besides being contoured and/or being provided with recesses from below to yield desired stiffness and/or clearance, such plate-structure can be made with downturned flaps at the edges of a sheet for the working surface. In such flaps, directly or indirectly being in contact with the placement surface, the possibly adjustable means for relative level-placement might be situated, the height of the flaps proper substantially could be determining for the relative level-placement.

Advantageously the invention's holder also can be made, so that the current placement plane for the at least one portable computer the holder is positioned in functioning relationship to, at least partly and possibly indirectly is defined by means of direct contact between the portable and at least some of the holder's means for relative level-placement, such placement means also allowing for—possibly repeated—placement and interaction-related fixture/support of the portable computer concerned, in different positions, which mutually might be turned and/or translated on this placement plane; likewise such placement means can define possibly different placement planes for at least one other portable computer, which the holder alternatively might be positioned in functioning relationship to.

From the direct contact from the holder to the portable computers concerned, achieved in this way, it has become easier to make positioning in the mutual functioning relationship secure and unambiguous, as now only to a lesser degree or not at all, it is necessary to take the condition of the elsewise common placement plane into consideration, such plane until now might have been present “on the conditions of the surroundings” (e.g. might have been constituted of the top face of a half-height wall structure of raw bricks).

Also a holder according to the invention comprising means to define one or more placement planes, of course, should have means to allow for positioning of the invention's holder in relation to a supporting/loadbearing structure in the surroundings. This is implied anywhere in this application; in the claims, too.

Adjustments in level and in the physical or ideal placement plane below the holder's working surface, to a high degree can also be facilitated by the holder's placement means, advantageously for each portable computer, comprising means making it up for the whole placement plane, which according to earlier mentioning can be reduced to relevant loadbearing-points or -surface elements for the model of portable computer concerned.

Also the placement means now can be configured so the unambiguous position of a portable computer can be kept during the incidental or necessary influences from forces from different directions, that the portable computer might be subject to during use with the invention's holder.

Very simply the placement means can consist of a plate, the top face thereof being located in the placement plane and having a surface area extending in desired degree and direction farther than the “foot print” of the current portable computer. Adjustment of a portable computer in the placement plane is thus performed by pushing the computer on the plate to the desired position, which might be marked for easy repositioning. In this relation all known means and methods for unambiguous repositioning and/or fixing might be used, e.g. rulers and/or guide pins.

The invention's means for unambiguous positioning and stabilization can be shaped in cooperation with one or more suppliers/designers or the like of portable computers to exploit suited openings, recesses or points/faces of attack, that already exist or are agreed to be formed on such portable computers. Such means might be shaped with a protected, registered design. E.g. an unambiguous positioning and adequate fixing can be achieved by means of a single pin projecting upwards into the lower part of the portable computer from a plane physical placement surface, if the pin posesses a fit into a corresponding recess in the computer, sufficiently free of twisting and linear movement in the placement plane. Fixing by means of a thread from below through such fixed pin might render a physical placement plane superflouos.

(Especially Re. Claim 5:)

By application e.g. in an office environment, the width of the working surface's area to the sides and the depth in direction towards the user beneficially can be extended as desired, e.g. to a width of approx. 1.6 m often found at ordinary office writing tables. The part of a working surface of extended depth situated behind the ready-folded screen has—as mentioned above—no significant value of use for the user of this screen's portable computer and can with advantage be exploited for placement of one or more other portable computers. Thus the holder according to the invention can comprise placement means for further portable computers, so that the relatively large depth of a working surface is exploited from counter-directions, as the portable computers then can be positioned with the backs of the screens mutually facing (“dos-a-dos”). Especially at such designs of the invention's holder comprising more, simultaneously “dos-a-dos”-positioned portables in use, where the distance from the user's eyepoint to the displaying area of the relevant screen is relatively small, the holder's placement means can be designed, so the “dos-a-dos”-positioned portable computers mutually are laterally offset, thus avoiding the legs/feet of the users concerned colliding during working in their normally sitting position at the invention's holder.

It also being possible on the holder according to the invention to work out placement means for positioning portable computers laterally juxtaposed, suitably spaced, it is possible by means of the holder to establish workplaces occupying just a minor floor space. At the same time users positioned side by side and/or askew, mutually facing, can use the adjacently situated areas of the working surfaces one after the other or in cooperation, e.g. if more users during their work having an individual portable computer at their disposal, have to mutually discuss details form a large rolled-out architect's drawing.

Portable computers, which are exploited in the same holder of the invention, do not need to be of similar physical dimensions as the design of the placement means can allow for the positioning of portable computers of different sizes one or more places.

A holder with an embodiment as just described, can also specifically be designed as a conference/meeting-table or as a modular component for a system with a similar function. Here the advantage is, that each participant in the meeting can bring one's own model of portable computer. The participants' fingers/hands can be situated at a lower level than the working surface during keying-in/inputting, whereby this activity can remain personal. With a suitable communication to/among the placed portable computers the participants also might be able to mutually communicate about informations commonly accessible via their individual screens. A meeting can also consist of participating in a computer-related game.

Beneficially the invention's holder therefore can be designed to be placed in functioning relationship simultaneously to more—not necessarily similar—portable computers, whereby the current physical or ideal placement plane for the portable computers concerned can be shared and/or individual, and whereby the working surface between each displaying area concerned and the user thereof can be a part of and/or consist of—possibly a part of—a discrete section of a larger substantially even working surface, which besides for the user concerned, also can be useful for other purposes.

Remembering what mentioned earlier, it is within the scope of the invention to let the placement means wholly or partly being made out of a specificly adapted/constructed fixing-device for a portable computer concerned, that can be interchangeable and does not need to contain or presuppose presence of physical elements of the placement plane, which then the fixing device defines indirectly.

(Especially Re. Claim 6:)

Larger or smaller parts of the area of the working surface of course can be manufactured from transparent material, also including the shaping as a net, a grid or the like comprising openings, as users who are not fully familiar with the input means of the portable computer concerned below the working surface, thereby can achieve an increased operational speed and accuracy, as they through the working surface can watch both the upfacing input means and their own fingers.

As mentioned the different portable computer models often have differing keypads regarding both spacing between the key centers and the extensions of the key surfaces. For reasons related to available space (the keys not to be inconveniently small and/or too closely spaced) the number of keys is also reduced more or less compared to the more than 100 keys, which besides possible special keys for more or less standardized use, are found on conventional, separate keyboards with a standardized layout re. key size, position, and function, especially aimed for office use (a window-based control software almost defines a de-facto standard for the layout of such keyboards). Many of the keys from a portable computer's keypad are often assigned to supplementary combined functions, which can differ among models, to achieve the same number of functions with the portable's keypad as found on a “standard keyboard”. Therefore many users of portable computers experience the problem, that their net key-in speed because of many key-in errors, which must be corrected, is quite small on a portable computer, especially if they shift between differing portable computers—what is the source of much annoyance and a heavy waste of time.

By further adapting the invention's holder to also constituting a preferably horizontal supporting substructure or a location surface for a “standard keyboard” and/or other manually operated separate input means (e.g. mouse, trackball, pen, digitizer, specialized keyboard, drive) communicating via one/more ports with the portable computer utilized, the great advantage is achieved, that the user now can keep her/his high net key-in speed and/or other high net input speed during use of optimized input means, elsewise only accessible at a desktop-PC/workstation. Especially if the holder according to the invention is designed, so the separate input means communicating with the portable computer are optimally positioned a bit raised above the thighs of a sitting user in a distance of reach to the keys/input means adapted for approx. vertical upper arms and horizontal forearms, most users with the invention's holder with a portable computer can be offered a working situation, which these users will find substantially improved compared to an ergonomic optimized working situation at comparable use of a desktop-PC/workstation, as the screen of the portable computer by means of the inventive holder can be given the lowest possible position of the displaying area in relation to the working surface, still maintaining a possibility for adjustment of inclination towards the user.

Preferably the holder according to the present invention therefore can also comprise supporting means, preferably for loadbearing and/or support of additional and/or substituting input means, ports and/or drives for at least one portable computer, to which the holder is placed in functioning relationship.

The location of input means close to the user achieved by use of the supporting means, yields the further advantage, that the screen of the portable computer used can be positioned more distant from the user, whereby the working surface between the user and the screen can be increased in the depth direction.

(Especially Re. Claim 7:)

For a further advantage the invention's holder can comprise means for relative shift and/or securing of the position of the supporting means compared to the working surface.

Such means can allow the supporting means being positioned according to the user's wishes, e.g. between her/him and the working surface, in below the working surface, or at places herebetween. By providing these shifting/securing means, the supporting means e.g. can be designed as a horizontal, plateshaped, towards the user relocatable unit, which not in use can be preferably linearly guided in—and in simple cases in nothing but a horizontal direction—above or below the lower part of the portable computer, neither the position of the input means on the location surface of the supporting means, nor the functional preparedness elsewise of the portable computer having to be influenced by this or by a counterdirected corresponding displacement. So the invention's holder can make up a configuration comprising an immediately operable portable computer, where the holder not utilized by a user, with or without the portable computer and input means, shows a small depth, because the supporting means comprising the elsewise untouched and operable possibly present input means, can be located below the (space for the) portable computer and the working surface. Such relocation means also beneficially can comprise hinges and pivoting levers, if e.g. because of a tall computer lower part and/or a thick structure of a working plate, possibly in combination with an input device of relatively extended height (e.g. a joystick) on a thick plate for the supporting substructure, it should be desired to let the supporting means moved out towards the user, being subject to a substantial especially vertical downwards movement at the beginning of relocation in below the working surface and the (space for the) portable computer, the relocation then being terminated with a mainly horizontal movement. Such a movement can be realized by means of radius arms in a part-circle motion, where multiple arms can be syncronized to maintain an e.g horizontal location surface of the supporting means. An almost pure vertical motion at the end of “moving-out”-sequence can in relation to the securing means also be used for level-adjustment of the supporting means compared to the user/working surface.

(Especially Re. Claim 8:)

If the user's normal needs for input are fulfilled by the input means placed on the invention's supporting means or in other ways are fulfilled, so there is no need for the user to operate the input means in the lower part of the portable computer, to which the inventive holder is placed in functioning relationship, the requirement for clearance above the portable computer's lower part is reduced to a need for a small security-distance only to hinder unintended damage and/or operation of the upfacing input means from the downfacing structure for the working surface, that e.g. might be caused by some downward flexing from a load on the working surface.

Especially following an increased distance of the screen from the user, at a small clearance and at input means in an elevated position on the supporting means in front of the working surface, it might be difficult for the user to reach in below the working surface to utilize a drive/port in the lower part of the portable computer. The use of alternative, separate, communicating drives/ports, e.g. located on the supporting means, yields an easier access for the user, but is a costly solution.

Therefore with advantage at least a part of the working surface in the form of one/more hatches/sections/parts or in its unity can be openable, pivotable and/or slidable compared to the remaining structure of the holder.

In this way the access to—possibly pop-out type—ports/drives in the lower part's side walls can be facilitated by admittance from above. In this connection also the whole—or essential part(s)— of the working surface can be upwardly openable or/and slidable compared to the remaining structure of the holder. These relatively moveable part's properties can also be utilized when the functioning relationship between the invention's holder and one or more portable computers is to be established or discontinued.

(Especially Re. Claim 9:)

Beneficially the inventive holder can be embodied as a furniture(-system), which can be constructed from adjacently positioned and/or mutually attached modular units and/or elements herefore; the holder then can be given supplementary functionality and properties possibly known from especially furniture for office use.

Thus the working surface can be combined from surface elements located in substantially same plane, whereof some might represent the surface of adjoining or attached units such as office furniture modules.

The working surface's limiting edge towards the user can be linear, but other shapes are also possible. The edge concerned can e.g. in the plane of the working surface have one or more angular breaks or be curved, wholly or partly around the user. With such a configuration, a part of the working surface near the user, being used as a placement surface for input means (especially keyboard and pointing means/mouse), and the user during her/his use hereof thus being able to rest her/his forearms/elbows on the part of the working surface curved/angled nearer around to the upper part of the body, a holder according to the invention can be provided, offering good ergonomics also to users, whose work situation e.g. comprises word processing using a computer, writing from draft/manuscript for a longer period of time. Especially if the working surface also is universally level-adjustable, the user thus can be standing or sitting, a holder according to the invention also will be able to meet the requirements/recommandations from e.g. the Danish authorities regarding furniture for computer-assisted-working used professionally, allowing the user more than two hour's daily working time.

One or more users placed e.g. in an aperture in the working surface can with the invention's holder be given opportunity to have more portable computers at their individual disposal, depending on the direction the user adresses.

Of course, in arrangements scoped by the invention's holder for at least one portable computer, also computers and devices of desired other types can form part.

Self-evident, within the scope of the invention all known means can be used in the construction of the e.g furniture related structure and details comprised, including adjusment of level in relation to a supporting surface in the surroundings.

In some situations of use it can be beneficial to let the width of the working surface in one or both lateral directions surpass the width of the lower part of the portable computer below the plane of the working surface. The user is then given opportunity to have e.g. several written sheets of paper of e.g “letter” or “legal” size (279.4*215.9 mm (˜8.5*11 inch) or 355.6*215.9 mm (˜8.5*14 inch), respectively) lying laterally spaced on the working surface, so that e.g. comparison of information from these sheets and simultaneous use of the computer is facilitated.

The depth of the working surface in front of the screen towards the user of course can be adapted to the intended situation of use. For office use the depth suitably can be approx 0.3-0.4 m corresponding to the height of an A4-sheet or of a ring/file binder. By this the user can e.g. read, write and/or handle paper of standard size, while such paper is placed on the working surface in front of the screen during the use of the portable computer.

Such handling activities of paper-related informations is very common in connection with exploitation of portable computers in the office-like environments mentioned, and can—as remarked—be performed under substantially improved ergonomic conditions by means of the portable computer concerned being placed in functioning relationship with the holder according to the present invention—also during e.g. teleworking in more private surroundings.

Even if one might imagine some apparently visual resemblance between the invention's holder in one of the later mentioned embodiments and known so-called “computer-tables” mainly used for ordinary stationary PC-combinations, a “computer-table” is not a relevant alternative to the invention's holder, as “computer-tables” do not allow for the location of the working surface just in front of the portable's displaying area, that is acquired by the invention's holder, as “computer-tables” do not possess the means for such location.

(Especially Re. Claim 10:)

The inventor of this invention has also perceived, that e.g. a separate flat screen of the type found in portable computers, comprising a foot/stand, by placement in functioning relationship to the invention's holder by use of the holder's placement means, as a special feature can offer to a user the same visual benefits as can be acquired for a portable computer functionally related to a holder acording to the invention.

Therefore a holder according to the invention preferably can be used by placing the holder in functioning relationship to at least one device containing a screen, with the understanding that this device by means of the holder's characterizing means as seen from the user's eyepoint of view is positioned according to the same visual principles for the position of the displaying area relative to the first edge of the working surface as can be realized for at least one portable computer, the holder can be placed in functioning relationship to.

In excess of the appended claims this application also comprises a drawing.

### SHORT DESCRIPTION OF THE FIGURES

The drawing shows more examples of embodying a holder according to the invention. These shown examples can in no ways be regarded as restrictive for the scope of the invention defined by the claims. The examples shown are selected with the purpose of giving the following detailed description of the invention.

From the drawing,

FIG. 1 shows—orthogonally seen from the right side—a simple holder according to the invention, especially for placement on a horizontal substructure; also a portable computer with functioning relationship with the holder is shown;

FIG. 2 shows the same holder as shown in FIG. 1—but seen orthogonally from the front;

FIG. 3 shows—orthogonally seen from the left side—a portable computer and a second inventive holder, adapted also for mounting to a vertical substructure;

FIG. 4 shows the same holder as shown in FIG. 3—but seen orthogonally from the front;

FIG. 5 shows—seen orthogonally from above—a third inventive holder ready for use with a portable computer,

FIG. 6 shows—seen orthogonally from the left side towards the section plane—the holder shown in FIG. 5 sectioned at the line V-V in FIG. 5; and

FIG. 7 shows—seen orthogonally from the front—the holder and the computer shown in FIG. 5.

### DESCRIPTION OF EMBODIMENTS

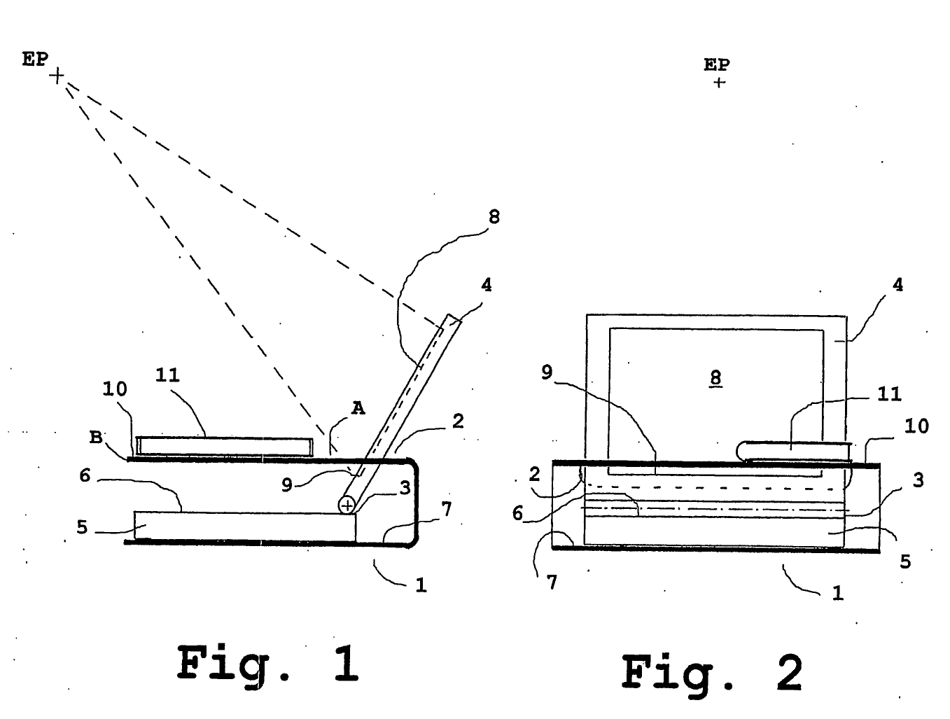

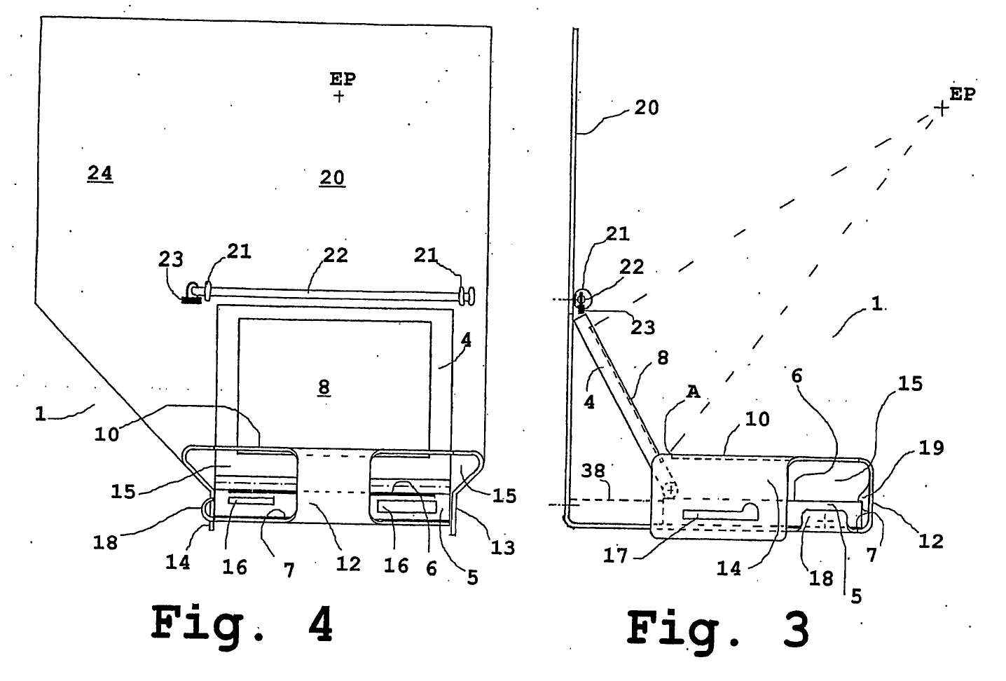

The holder 1 according to the invention, shown in FIGS. 1 and 2, is manufactured from a suited sheet/plate material and has roughly the shape of a U-profile lying on the side. The holder 1 is positioned relative to the surroundings by resting on the downfacing U-profile flap and/or being mounted with the back of the U-profile to a wall or stand. At the root of the upper flap an opening 2 is provided (see esp. FIG. 2), wherethrough the ready-folded screen 4 of a ready-for-use portable computer 3 (comprising desired and/or possibly necessary external physical connections or accessories—not shown) is protruding, as the portable's lower part 5 comprising the upfacing input means 6 such as keypad and pointing means is positioned on the top face of the lower U-profile flap, which therefore is both theoretical placement plane and physical placement surface 7 for the note-book computer 3. The opening 2 might be provided by removing a single piece of material from the material for the U-profile before or after the shaping to a U. At the placement in the holder 1 the portable computer 3 is inserted through the opening 2, the lower part 5 or the screen 4 first. This depends on the actual physical dimensions, whereby the dimension of the holder I, also including the length of the U-profile and the dimensions of the opening 2, might be determined in relation to the model(s) of portable computer(s) 3, to which the invention's holder 1 is intended to be used. Special combinations of dimensions can hinder removal of the portable 3 from the holder 1, when this afterwards is locked to a substantially vertical wall/structure part protruding behind the pivoted screen 4. The holder 1 is positioned at a level normally suited for a sitting or standing user, of whom only a formalized eyepoint of view EP is indicated.

In this example the upper flap of the U-profile constitutes the working surface 10, which (as seen from the user) has a first limiting edge A near in front of the screen's displaying area 8, that edge here being coincident with the opening's 2 edge nearest to the user. From here the working surface 10 extends in direction towards the user until delimited by the front edge B of the upper U-profile flap located opposed the first limiting edge A. Laterally the working surface is delimited by the lateral edges of the U-profile (see FIG. 2). Some material 11 is lying on the working surface 10, e.g. a book for notes being useable for the user simultaneously with the use of the portable computer 3 in the inventive holder 1, normally involving a visual communication via the screen's 4 displaying area 8 and a reach with the users hand(s)/finger(s) in below the structure of the working surface 10, i.e. here the upper U-profile flap, to operate the input means 6. The means for relative level-placement of the portable 3 compared to the working surface 10, are in this example non-adjustable and consist substantially of the back of the profile being adapted to the dimensions of the laptop concerned, and of the thickness of the profile material. The means for level-placement have the effect, that the user from the eyepoint EP has a non-hindered sight to the full displaying area 8 of the screen 4, as the portable 3 and thus the screen 4 by means of the placement means has been positioned, so the (dashed) line of sight from the eyepoint of view EP can pass by the first limiting edge A of the working surface and reach down to the lower-border 9 of the displaying area 8, despite the lower border 9 of the computer model 3 shown here is situated at a lower level than the working surface 10.

From FIG. 1 is to be seen, that the invention's holder with a portable computer at most requires a small shift in the user's line of sight and distance of focusing at shifting between regarding the screen's displaying area 8 and the material 11 on the working surface 10. Also to be seen is, that the user does not need to maintain her/his arm partially stretched out freely raised over the working surface 10 and possible material 11 thereon, to operate the upfacing input means in the lower part 5 of the portable computer 3. Especially if the operation of the input means 6 can be restricted to operation of pointing and/or confirmation means, which easily are operated “in the dark”, the working surface 10 or the whole holder 1 can be manufactured form opaque material, e.g. sheet metal, plywood or other sandwiched plate material, including sophisticated honeycomb-plates, advanced fiber-composit technology also being applicable, as it normally is desired to achieve a stiff and stable working surface with limited thickness of the underlying structure. By making especially the working surface 10 from a transparent material, e.g. glass or plastic, the user can be given a visual aid in localizing the keypad and/or its keys etc.

The invention's holder 1 in FIGS. 1 and 2 offers unhindered access to drives/ports etc. in the lower part 5 from three sides. Possible admittance to backfacing ports is normally established by means of cables connected in relation to the placement of the computer into the holder. Is the use of a port on the back side of the lower part specifically desired, requiring unhindered line of sight, e.g. an IR-port, suitable cut-outs can be made in the holder material; likewise of course a possibility for placement of the communication partner—being e.g. a mobile telephone comprising an IR-port—can be established. It might be suitable to fix the portable 3 to the holder I, e.g. by means of fasteners from/through the lower U-profile flap, especially for maintaining of communication pathes for ports (e.g. direction of JR-radiation).

The holder 1 according to the invention, shown in FIGS. 3 and 4, can also be made from bent, e.g. stainless, steel sheet and exhibits also a working surface 10 near in front of the screen's displaying area 8, being delimited by the first, usually rectilinear limiting edge A (FIG. 3). As in the former example the levelling means consist substantially of an approx. vertical panel; here 12, connecting the working surface's 10 material with that of the placement surface 7, thereby defining the distance therebetween, so the user from her/his eyepoint of view EP has unhindered view of the whole displaying area 8. The vertical panel 12 here is led to the working surface in front of the computer's lower part 5, and is together with the right and left vertical flaps, 13 and 14 respectively, from the downwardly bent side panels from the working surface 10, consisting means for partly securing unambiguous placement of the computer's lower part, partly securing, it can not be removed in the corresponding directions. Between the holder's 1 vertical panel 12 and the downbent side panels, openings 15 are defined giving access for the users hands/fingers to operate the upfacing input means 6 situated below—and covered from—the working surface 10. From FIG. 4 is to be seen, that the openings 15 also are offering admittance to ports/drives/places for drives 16 in the front of the computers lower part E.g. from the sheet material else not utilized for reasons of the openings 15, one or more inwardly bent profiled tabs 19 can be formed to define the position of the front edge of the lower part 5 with desired accuracy in direction towards the user and upwards. With the aperture 17 shaped for its purpose in the left side flap 14, an intended desired user admittance to an, e.g. diskette-, drive situated in the lower part in line with the aperture is created. By this a user e.g. temporarily can locate a memory-unit in a drive of the portable computer and utilize brought data or get access to data organized in the portable (e.g. code-files for internet-banking or e-mails) during a short term use of the holder with the portable computer. On the contrary, user-access to the computer's reset-button is blocked by a tab 18 from the holder's sheet material suitably bent up blocking for this button. Behind the computer the sheet material from the extension backwards of the placement surface 7 is bent upwards to consist a substantially vertical backpanel 20 making the holder 1 suited for placement onto a vertical wall by means of known means and methods herefore.

The portable computer comprising the lower part 5 and the screen 4, shown in FIG. 3, can not undamaged be removed as a unit from the holder 1. Placement/removal of the computer therefore is performed through an adapted opening in the back panel 20, not visible in FIG. 4. If the holder 1 is secured to the stationary vertical wall, not shown, comprising e.g. two eye screws 21 or the like, by means of a padlock 23 through a hole in a locking pin 22 with head, both the computer and the holder are secured against unauthorized removal, thus being suited for use in public environment by anonymouos users. If the holder 1 is manufactured from a non-transparent material, e.g. fiber reinforced plastic, the user might be offered visual assistance at the use of the input means 6 anyway, as the relevant part of the working surface 10 can be made of transparent material bedded in during the manufacture of the holder, or be made exchangeable as a plate being slidable from behind into a guideway through the same opening in the back panel 20 as used for the computer 3. Should it further be desired to secure the screen 4 against being collapsed and thus being damaged from the first limiting edge A of the working surface, e.g. a profiled bar from sheet material, not shown, can be put over the eye screws 21 and be secured with the locking pin 22 with the padlock 23. A person skilled in the art can easily shape such a profiled bar, so it keeps the screen 4 against the back panel 20 in the position shown in FIG. 3. If desired, the skilled person also can perform a secured cover shown dashed at 38 in FIG. 3 to protect possible cable connections from the wall to the back side of the lower part and/or to secure the lower part against backward movement. Should another computer model currently used be removable past the working surface's first limiting edge A, the skilled person also easily can perform suited means hindering non-authorized removal this way; such person also being able to increase the stiffness of the construction by prolonging the downbent side panels 13 and 14 in the depth direction towards the back panel and by suited fixing hereto and to the placement surface and the backward extension hereof, e.g. by welding, to make a clearly much stiffer box-like construction. Of course a holder according to the invention can be given a more visually appealing design/appearance for together with a functionally related portable being suited for advertising purposes.

In FIG. 4 the back panel 20 is shown being non-symmetrical with a left wing 24 adjoining the large area facing the user and especially being visible above the screen. The visible faces of the holder 1 can make up for backing for adds, instructions or the like; also the elevated and/or lateral areas of the back panel 20 are suited for placement of mirrors or cameras. Namely if the use of the invention's holder comprises the user's handling of sensitive informations about economic or personal matters or the like during the use of the portable computer, the holder beneficially can be equipped with one or more mirrors giving the user retrovision behind her-/him-self during the use of the holder. By this the user can protect her-/him-self from being spyed on from near behind positioned persons for e.g. key-in codes. Alternatively or additionally the holder can be provided with one or more cameras communicating with the portable computer and showing exposure of the area behind the user on the screen's displaying area in one or more “windows”. The camera/mirror function can also offer the user possibility to mirror/watch her-/him-self as usual. In this connection camera pictures can, possibly to wish, be shown “as seen” or mirrored and might also be incorporated in some surveillance system. If use of the invention's holder with a portable computer requires payment, a payment receiving/recording unit, e.g. a card reader, also can be positioned on or in the back panel 20. By designing the backpanel with a lateral wing as 24 to both sides and bending or folding these wings' free side edges forwards towards and partly around a user, he/she can be offered a more undisturbed situation during the use of the holder.

The reader can easily imagine her-/him-self a holder according to the invention consisting of one as show in FIGS. 3 and 4, all structure below the placement plane/surface 7 being removed together with the back panel 20 and other supplementary locking/fixing means. A holder thus disclosed will be suited for placement e.g. near the edge of a table top simultaneously making up for the placement surface for the portable computer. The levelling means here will especially consist of the downbent side panels 13 and 14, as these—at a suitably large extension in the depth direction—might render a vertical panel as 12 in front of the lower part's front superfluous. E.g. in relation to this the material (combination) for the working surface might be profiled to achieve increased stiffness.

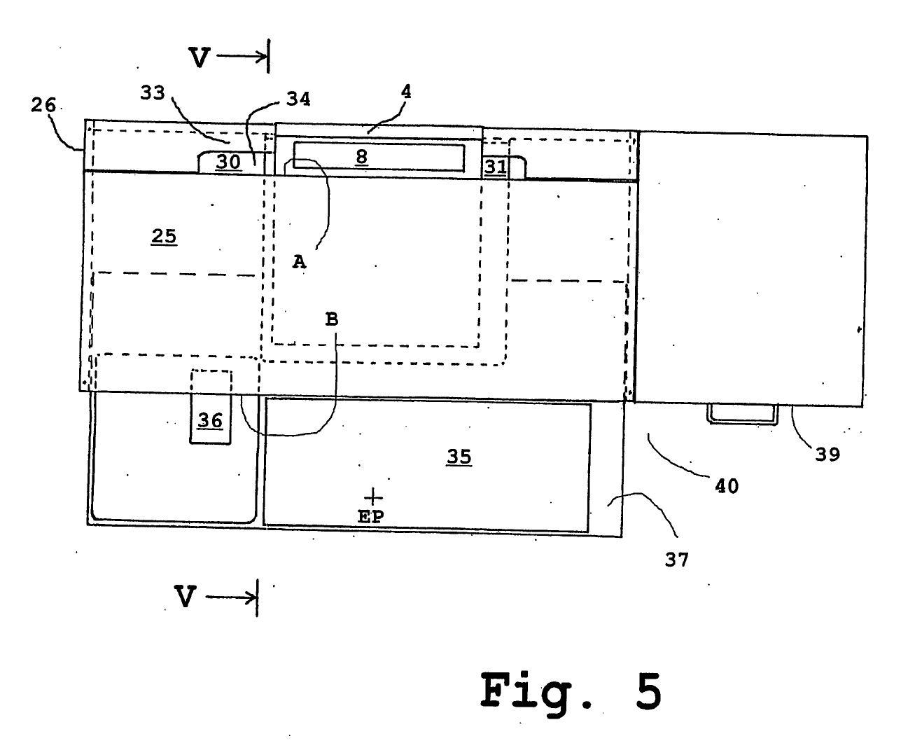

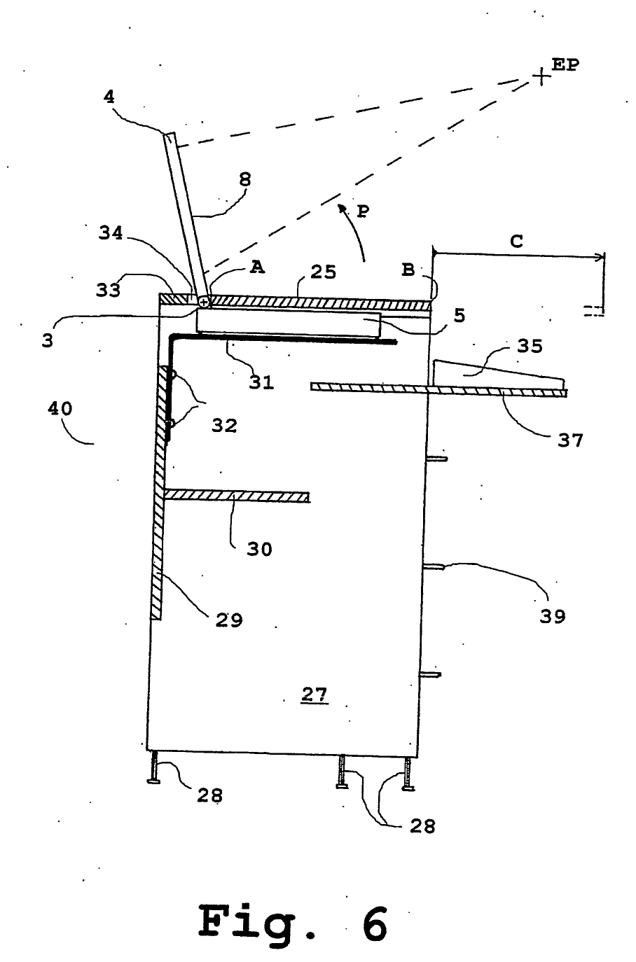

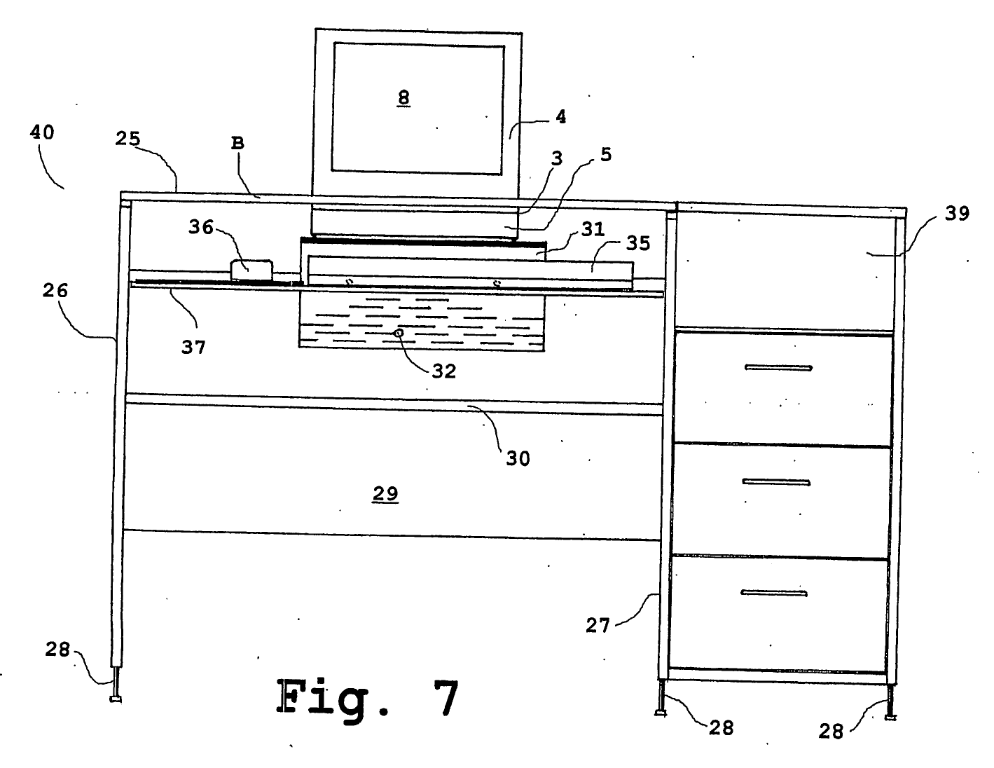

The invention's holder 40 in FIGS. 5, 6, and 7 is as an example to a large extent constructed according to principles and from materials and components often used among others in that part of the furniture industry producing easy-assembled furnitures of plates, e.g. from coated chipboard. The holder's primary working surface 25 in one piece of e.g. 14 mm thick, veneered blockboard for achieving the desired stiffness, rests indirectly on two vertical side panels 26 and 27, as the working surface 25 is made slidable in its horizontal plane a distance C (FIG. 6) in the direction of a not shown user, and also is made upwardly pivotable in direction of arrow P around a hinge axis at the first limiting edge A of the working surface 25. Such pattern of movement can e.g. be established by on or at both the upfacing edges of the side panels to place a linear guide below a hinge under the underside of the structure of the working surface, comprising relevant mutual fixing; these guides only being indicated in FIGS. 6 and 7. The lower edges of the side panels 26, 27 can rest on a usually substantially horizontal substructure not shown, possibly via elevative adjustable elements, caps, lockable wheels or other known comparable supporting/relocation components 28. Due to the minor stiffness against turning/torsioning around the longitudinal axis of the linear guides below the working surface, the mutual stiffness between the side panels 26 and 27 is established by a connecting back panel 29 and a shelf panel 30, both being semipermanently attached due to disassembling of the holder 1 later on. Of course the stiffening section with T-profile achieved from the plates 29 and 30 shown in FIG. 6, instead can be parted, have another profile or be a closed section, taking into account the relevant principles from the theory of stability. Side panels and/or other relevant parts of the holder of course can be made, comprising apertures, recesses, and/or possibly partially as frames, legs or structure-parts of other material. On the top edges of the side panel parts farthest from the user can lie a plate shaped adapter piece 33, the areas at the ends being. adjacent the extensions of the working surface's 25 first limiting edge A, a cut out 34 being located therebetween. By this an opening for the screen is defined in the plane of the working surface. The adapter piece 33 can consist a (secondary) part of the working surface or can just have anesthetic function of a desired design. The back edge of the adapter piece 33, the first limiting edge A of the working surface 25, or other edges delimiting the working surface, might be provided with a raised barrier to hinder passage of articles form the working surface past the actual barrier. On the back panel 29 an L-profile is hung—as shown in FIG. 6—e.g. a 90°-bent 1-3 mm thick slot perforated steel plate 31. This plate is hung by some flangehead screws 32 being screwed into the back panel 29 through some of the plate's horizontal slots, whereby the metal plate is fixed or can be laterally slidable on the screws 32 as the screw heads then keep the steel plate within a defined small distance from the back-panel 29. The placement plane/surface might be sloping. E.g. it can be brougt to slope in direction towards the user EP to achieve a clearance above the portable's 3 lower part 5 increasing towards the user, by letting the length of the most elevated screws 32 allowing for the plate 31 near the bend becoming situated in a substantial distance form the back panel 29. Anyhow the structure of the holder defining the placement plane can be designed in any desired way to fulfil the requirements defined, just as any known means for adjustment and fixing can be brought to use within the scope of the invention. A ready-folded portable computer 3 comprising screen 4 and lower part 5 is positioned with functioning relationship with the holder 1 according to the invention, by the working surface 25 at least partly being positioned up above the portable's lower part 5, the first limiting edge A being near in front of the displaying area 8, and an opposed limiting edge B being located towards the user, as the means for level-placement secure placement of the portable 3 at a level relatively to the working surface 25, that the whole displaying area 8 is visible above the working surface from the user's eye point of view EP (see FIG. 6). As this example of an embodiment of a holder according to the invention has supporting means in the form of a supporting plate 37 for supporting the separate input means sufficient for the user concerned, e.g. a standard keyboard 35 and a mouse 36 on a mouse pad, all being positioned on the supporting plate 37, the lower part 5 can be kept positioned with a small free security clearance below the underside of the working plate. The level adjustment for this can be performed by placing the screws 32 penetrating some of the plate's 31 horizontal slots, in the relevant number of a pattern's predrilled holes in the back panel 29, so an indexing in level can be performed in steps of e.g. 1 mm. A pattern of holes through the substantially horizontal flap of the L-profile can be utilized for establishing a guide on the placement plane and for fixing of the portable. To allow for putting the separate input means 35, 36 aside, not wished to be used, the supporting plate 37 is moveable, so the front edge thereof towards the user can be brought substantially in, below the working surface (the corresponding guides according to well known principles not being shown). Hereby the holder will appear with less depth dimension and is e.g. easily wheeled through a narrow door opening, the functionality not elsewise being affected. A sitting person of normal size will often find a level of the top face of the supporting plate of 60-65 cm above the floor level as suitable, but depending of the height of the separate input means located on the plate. With a level of the working surface 25 of e.g. 70-75 cm above the floor level, that the working surface is also usable as an ordinary top face of an office desk, it is possible for many types of portable computers in connection with a suitably thin working and supporting plate, placement means with small effective height, and low separate input means, especially a keyboard 35, to put the input means aside by sliding the supporting plate comprising the separate input means horizontally in below the placement means carrying the portable's lower part, what can be utilized, if the holder in direction from the user towards the screen only has a limited depth, e.g. 40 cm (this opportunity is for the example demonstrated by observing FIGS. 6 and 7). Other directions for a rectlinear guidance can also be used without the normal to the supporting plate having to alter its direction during the movement. The supporting plate's normal does not have to alter direction during the movement either, if instead a solution is chosen, where the supporting plate—as earlier mentioned—can be swung downwards in below the working surface and the portable, e.g. guided of three radius arms—one at each side at the front edge and one behind, e.g. connecting to the back panel 29.

By suitably designed securing means, especially the substantially vertical part of the pivoting movement might be utilized for level-adjustment of the supporting plate and the separate input means in the ready-to-use condition relatively to the level of the working surface. Also this level relatively to the floor level can—as mentioned—be adjustable via adjustable components in the side panels or the like, whereby the holder can be universally adjustable in level. Is the supporting plate moreover given an effective width of approx. 70 cm or more and a suitable large depth, e.g. 18 cm or more, the invention's holder will easily could be produced to a condition obeying serious recommandations/standards for a professionally used computer workplace. With a depth of the working surface between the user and the screen of approx. 35 cm and a width of the working surface of e.g. 120 cm, e.g the rightmost approx. 40 cm hereof being situated above a, possibly retrofitted, drawer module 39, it is thus possible to establish a computer workplace with a holder according to the invention and a hereto functionally related portable computer, on a square area between walls of the sidelength of 120 cm, an access door for a possibly physical workcell of less than 1.5 m² so constructed, best being a sliding door or of an outwardly opening type. Often the holder comprising the portable is just positioned against a wall, yielding visually relaxing surroundings for the screen. If the portable is desired to be removed, e.g. because a user wants to take it along and another user is going to take over the place bringing her/his own portable computer, the possibility for the sliding displacement of the primary working surface 25, earlier mentioned, gives room for such exchange, when the holder/the portable is positioned/arranged, so that the portable e.g. is not removable in a direction away form the user. The possibility mentioned earlier to swing up the primary working surface 25 near the user can be used to get access to drives, etc. in the portable's lower part, if such access is not available by directly reaching in for the lower part, or is not established by means of smaller hatches in the working surface.

With the embodiments of the invention's holder shown and described it is clear, that the holder according to the invention can be given physical expressions of very varying character—and therefore can be used for uncountable, in many cases still not realized, purposes—without therefore leaving the protected scope of the invention, that is defined by the appended claims, as any component(-group) being produced/marketed with the purpose of by constructing, retrofitting and/or rebuilding of some device (including an existing holder according to the invention) to yield a holder according to the invention, is ranked as such.

A table-/desk-like holder comprising a working surface, especially for at least one portable computer, maybe of short calculated service life, e.g. for use by one or more journalists/officials/participants at a major sports event, made from folded corrugated cardboard and financed by a sponsor in exchange for suitable advertising printing, also can be scoped within the present invention, as the working surface might be restricted to a relatively narrow shelf for smaller articles in front of the portable's screen, and the means for level adjustment then adapt the level of this working surface relative to the lower border of the displaying area of the portable computer placed in advance in a relatively fixed predefined position.

1. Holder for at least one portable computer,
the holder comprising a working surface substantially planar and defined by the upfacing surface of an underlying structure with one or more limiting edges,
the holder being positionable in functioning relationship to the at least one portable computer (3) comprising a lower part (5) and a relatively hereto ready-folded screen (4) comprising a displaying area (8) by the working surface for a user being useable simultaneously with said user's visual exploitation of the screen's displaying area (8) from her/his eyepoint of view (EP) substantially being positioned in front of the displaying area (8),
characterized in
the structure of the holder below at least a part of the working surface (10; 25) having a shape, so a first limiting edge (A) for the working surface (10; 25) can have a position substantially near in front of the displaying area (8) of the ready-folded screen (4) of the at least one portable computer (3), which the holder is positioned in functioning relationship to, and so that a limiting edge (B) for the working surface relative to the first limiting edge (A) can be positioned nearer to the user of the functionally related portable concerned, whereby at least a part of the working surface (10; 25) can be established up above the lower part (5) of the portable computer(s) concerned (3), between the ready-folded screen (4) and the user (EP) hereof, and
the holder having means (12/13, 14; 29, 31, 32) for relative level-placement of at least one functionally related portable (3) concerned comprising ready-folded screen (4), to at least a part of the working surface (10; 25) established thereupabove,
so that a desired part of, preferably the whole, displaying area (8) of the screen concerned, as seen from the eyepoint of view (EP) of the user concerned, by the effect of these means can be made visible above the first limiting edge (A), located nearer to the displaying area (8) and up above the lower part (5) of the portable concerned.

2. Holder according to claim 1, characterized in the delimiting edge of the working surface one or more places being provided with a raised barrier.

3. Holder according to claim 1 or 2, characterized in the means for relative level-placement being adjustable (29, 31, 32), whereby the theoretical placement plane for said at least one functionally related portable computer (3) concerned compared to the underside of the structure above said lower part (5), is adjustable in varying spacing and/or in varying slope, yielding a clearance above said lower part (5), preferably augmenting in direction towards said user (EP).

4. Holder according to one or more of the preceeding claims, characterized in the placement plane concerned for said at least one functionally related portable computer (3), at least partly and possibly indirectly is defined by means of a direct contact between said portable computer concerned and at least some of the holder's means (31) for relative level-placement, said means if desired also allowing for possibly repeated placement and operation-related fixing/support of said portable computer in differing positions, which might be turned and/or transposed on said physical or ideal placement plane, whereby the holder's means (29, 31, 32) for relative level-placement correspondingly can define possibly different placement planes for at least one other portable computer (3), which the holder alternatively is placed in functioning relationship to.

5. Holder according to one or more of the preceeding claims, characterized in the holder having means for simultaneous placement in functioning relationship with more—not necessarily similar—portable computers, as said portable computers' physical and/or ideal placement plane concerned, by said means can be made common and/or individual, whereby the working surface (25) between each displaying area concerned and the user hereof can be a part of and/or consist of—possibly a part of—a discrete section of a larger substantially even working surface, which besides for the user concerned, also can be useful for other purposes.

6. Holder according to one or more of the preceeding claims, characterized in the holder having supporting means (37) preferably for loadbearing and/or support of additional and/or substituting input means (35, 36), ports and/or drives for at least one portable computer (3), to which the holder is placed in functioning relationship.

7. Holder according to claim 6, characterized in the holder having means for relative shift and/or securing of the position of the supporting means (37) compared to the working surface (25).

8. Holder according to one or more of the preceeding claims, characterized in at least a part of the working surface (25) in the form of one/more hatches/sections/parts or in its unity being openable, pivotable and/or slidable compared to the remaining structure of the holder.

9. Holder according to one or more of the preceeding claims, characterized in the holder being designed as a furniture(-system), which can be constructed from adjacently positioned and/or mutually attached modular units and/or elements herefore; the holder possibly then being given supplementary functionality (29).

10. Use of a holder according to one or more of the preceeding claims, characterized in the holder being placed in functioning relationship to at least one device containing a screen (4), with the understanding that this device by means of the holder's characterizing means (A; 29, 31, 32) as seen from the user's eyepoint of view (EP) is positioned according to the same visual principles for the position of the displaying area (8) relative to the first limiting edge (A) of the working surface (25) as can be realized for at least one portable computer (3), which the holder can be placed in functioning relationship to.
